(19) United States
(12) Patent Application Publication
(10) Pub. No.: US 2026/0076050 A1
(43) Pub. Date: Mar. 12, 2026

(54) DISPLAY DEVICE AND ELECTRONIC DEVICE

(71) Applicant: SAMSUNG DISPLAY CO., LTD., YONGIN-SI (KR)

(72) Inventors: Ho Yun BYUN, Yongin-si (KR); Byoung Dae YE, Yongin-si (KR)

(21) Appl. No.: 19/097,927

(22) Filed: Apr. 2, 2025

(30) Foreign Application Priority Data
Sep. 11, 2024 (KR) 10-2024-0123604

(51) Int. Cl. H10K 59/131

(52) U.S. Cl. CPC H10K 59/1315

(57) ABSTRACT

A display device including: a display panel; a driver circuit connected to a pad of the display panel; and a first protruding pattern and a second protruding pattern disposed between a substrate of the display panel and the pad and protruding toward a terminal of the driver circuit, wherein an area of the first protruding pattern is less than an area of the second protruding pattern, and a thickness of the first protruding pattern is greater than a thickness of the second protruding pattern.

### CROSS-REFERENCE TO RELATED APPLICATION(S)

This application claims priority under 35 U.S. C. § 119 to Korean Patent Application No. 10-2024-0123604, filed on Sep. 11, 2024, in the Korean Intellectual Property Office, the disclosure of which is incorporated by reference herein in its entirety.

### 1. TECHNICAL FIELD

The present disclosure relates to a display device, and more particularly, to a display device designed to minimize the contact resistance between a display panel and a driver circuit, as well as an electronic device incorporating such a display.

### 2. Description of the Related Art

Organic light emitting diode displays are self-luminous and, unlike liquid crystal displays, do not require a separate light source, allowing for a thinner and lighter design. In addition, organic light emitting diode displays are gaining attention as next-generation display technology for televisions, monitors, and portable electronic devices due to their advantages including low power consumption, high luminance, and fast response speed.

### SUMMARY

Embodiments of the present disclosure provide a display device designed to minimize the contact resistance between a display panel and a driver circuit.

According to an embodiment of the present disclosure, there is provided a display device including: a display panel; a driver circuit connected to a pad of the display panel; and a first protruding pattern and a second protruding pattern disposed between a substrate of the display panel and the pad and protruding toward a terminal of the driver circuit, wherein an area of the first protruding pattern is less than an area of the second protruding pattern, and a thickness of the first protruding pattern is greater than a thickness of the second protruding pattern.

According to an embodiment of the present disclosure, there is provided an electronic device including: a display device including a screen, wherein the display device includes: a display panel; a driver circuit connected to a pad of the display panel; and a first protruding pattern and a second protruding pattern disposed between a substrate of the display panel and the pad and protruding toward a terminal of the driver circuit, wherein an area of the first protruding pattern is less than an area of the second protruding pattern, and a thickness of the first protruding pattern is greater than a thickness of the second protruding pattern.

According to an embodiment of the present disclosure, there is provided a display device including: a display panel; a driver circuit connected to a pad of the display panel; and a plurality of protruding patterns disposed between a substrate of the display panel and the pad, the plurality of protruding patterns protruding toward a terminal of the driver circuit, wherein the plurality of protruding patterns includes protruding patterns of different sizes and/or thicknesses.

### BRIEF DESCRIPTION OF THE DRAWINGS

The above and/or other features will become apparent from the following description of the embodiments, taken in conjunction with the accompanying drawings in which:

FIG. 1 is a plan view of a display device according to an embodiment;

FIG. 2 is a plan view of the display device without a driver circuit, a first circuit board, and a second circuit board of FIG. 1;

FIG. 3 is an enlarged view of area A1 of FIG. 2;

FIG. 4 is a cross-sectional view taken along line I-I′ of FIG. 3;

FIG. 5 is an enlarged view of area A2 of FIG. 4;

FIG. 6 is a cross-sectional view of the display device when a display panel according to an embodiment and the driver circuit are bonded parallel to each other;

FIG. 7 is a cross-sectional view of the display device when the display panel according to the embodiment and the driver circuit are not bonded parallel to each other;

FIGS. 8 and 9 are diagrams for explaining the effect of the display device according to the embodiment; and

FIG. 10 is a tomogram of a part of the display device according to the embodiment.

FIG. 11 is a block diagram of an electronic device according to one embodiment.

FIGS. 12, 13 and 14 are schematic diagrams of electronic devices according to various embodiments.

### DETAILED DESCRIPTION OF THE EMBODIMENTS

The present disclosure will now be described more fully hereinafter with reference to the accompanying drawings, which illustrate embodiments. However, the disclosure may take various forms and is not limited to the embodiments set forth herein. These embodiments are provided to ensure a thorough and complete disclosure, effectively conveying the full scope of the disclosure to those skilled in the art.

It will be understood that when a layer is referred to as being “on” another layer or substrate, it can be directly on the other layer or substrate, or intervening layers may also be present. The same reference numbers indicate the same components throughout the specification. In the accompanying drawings, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element. The designation of an element as “first” does not necessarily require or imply the presence of a second element or other elements. The terms “first”, “second”, etc. may be used herein to distinguish different categories or sets of elements. For brevity, the terms “first”, “second”, etc. may represent “first-category (or first-set)”, “second-category (or second-set)”, etc., respectively.

Features of various embodiments of the present disclosure may be combined in whole or in part. As will be readily understood by those skilled in the art, various technical interactions and operations are possible. The embodiments can be implemented individually or in combination.

The present disclosure relates to a display device designed to minimize contact resistance between a display panel and a driver circuit, improving electrical connectivity and device reliability. It achieves this through the incorporation of protruding patterns of different sizes and thicknesses positioned between the display panel substrate and the pad that connects to the driver circuit. The first protruding pattern has a smaller area but greater thickness than the second protruding pattern, allowing for enhanced contact force and penetration force. This design ensures stable electrical contact, even when the display panel and driver circuit are not perfectly parallel, thereby reducing signal loss and improving overall performance.

The technology is applicable to various next-generation displays, including OLED, quantum dot, micro-LED, and nano-LED displays, making it suitable for smartphones, tablets, TVs, wearables, and automotive displays. Unlike conventional designs where misalignment significantly reduces contact area and increases resistance, this approach maintains consistent electrical connectivity. By improving the fluidity of the non-conductive film (NCF) used in bonding, this disclosure further enhances adhesion and durability. This innovation is particularly beneficial for flexible and high-resolution displays, ensuring long-term performance and efficiency.

Hereinafter, specific example embodiments will be described with reference to the accompanying drawings.

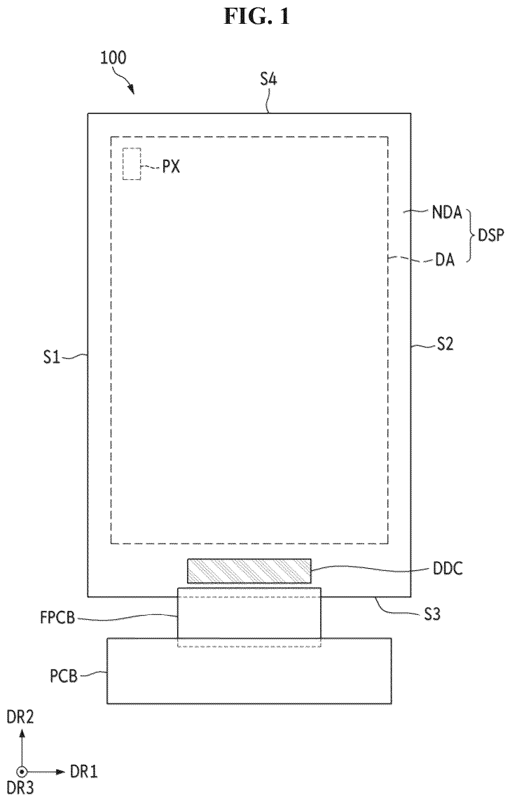

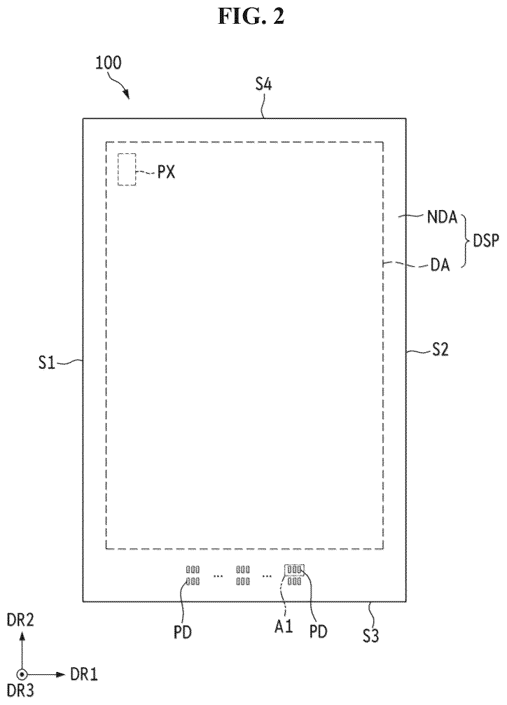

FIG. 1 is a plan view of a display device 100 according to an embodiment. FIG. 2 is a plan view of the display device 100 without a driver circuit DDC, a first circuit board FPCB, and a second circuit board PCB of FIG. 1.

Referring to FIG. 1, the display device 100 is a device for displaying moving images or still images. The display device 100 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and Internet of things (IoT) devices. These are presented only as examples, and the display device 100 can also be employed in other electronic devices.

The display device 100 may be a light emitting display device such as an organic light emitting display device including an organic light emitting diode, a quantum dot light emitting display device including a quantum dot light emitting layer, an inorganic light emitting display device including an inorganic semiconductor, or an ultrasmall light emitting display device including an ultrasmall light emitting diode such as a micro-or nano-light emitting diode. However, the present disclosure is not limited thereto. For example, the display device 100 may be a type of display device other than a light emitting display device. Embodiments in which the display device 100 is a light emitting display device (e.g., an organic light emitting display device) will be disclosed below.

The display device 100 may include a display panel DSP, the first circuit board FPCB, the second circuit board PCB, and the driver circuit DDC (e.g., a data driver circuit).

The display panel DSP may be a rigid panel that remains substantially undeformed or a flexible panel capable of deformation, such as folding, bending, or rolling in at least a portion. The display panel DSP may be integrated into the display device 100 in either an unbent state or a bent state in certain sections.

The display panel DSP may include a display area DA and a non-display area NDA.

A plurality of pixels PX may be disposed in the display area DA. The pixels PX may display an image. In addition, a plurality of gate lines and a plurality of emission lines connected to the pixels PX may be disposed in the display area DA. The display area DA may have various shapes according to the embodiments. For example, the display area DA may have a quadrilateral shape, a polygonal shape other than the quadrilateral shape, a circular shape, an oval shape, an irregular shape, or other shapes. In an embodiment, the display area DA may have a shape that matches the shape of the display panel DSP.

The non-display area NDA may be disposed around the display area DA. In an embodiment, the non-display area NDA may surround the display area DA. A gate driver and an emission driver for driving the pixels PX may be disposed in the non-display area NDA of the display panel DSP. The gate driver may be connected to the gate lines, and the emission driver may be connected to the emission lines. Gate signals from the gate driver may be supplied to the pixels PX through the gate lines, and emission signals from the emission driver may be supplied to the pixels PX through the emission lines.

A first side S1 and a second side S2 of the display panel DSP may face each other in a first direction DR1, and a third side S3 and a fourth side S4 of the display panel DSP may face each other in a second direction DR2. The first circuit board FPCB may overlap the third side S3. Here, the first side S1 (or the second side S2) may be longer than the third side S3 (or the fourth side S4). However, the present disclosure is not limited thereto, and the length of each of the first side S1, the second side S2, the third side S3, and the fourth side S4 may vary.

The driver circuit DDC may be connected to the display panel DSP. For example, the driver circuit DDC may be electrically connected to the non-display area NDA of the display panel DSP. The driver circuit DDC may include, for example, an integrated circuit.

The first circuit board FPCB may be connected to the display panel DSP and the second circuit board PCB. For example, a first side of the first circuit board FPCB may be electrically connected to the non-display area NDA of the display panel DSP, and a second side of the first circuit board FPCB may be electrically connected to the second circuit board PCB. The first circuit board FPCB may be, but is not limited to, a flexible film such as a flexible printed circuit board or a printed circuit board. For example, the first circuit board FPCB may be a flexible printed circuit board.

The second circuit board PCB may be electrically connected to the display panel DSP through the first circuit board FPCB and may exchange signals with the driver circuit DDC. The second circuit board PCB may provide image data, control signals, power voltages, etc. to the display panel DSP or the first circuit board FPCB. Active and passive elements may be disposed on the second circuit board PCB. For example, a timing controller and a power supply unit may be disposed on the second circuit board PCB. The second circuit board PCB may be, but is not limited to, a flexible printed circuit board or a rigid printed circuit board. For example, the second circuit board PCB may be a rigid printed circuit board.

The power supply unit may supply power voltages to the pixels PX, the gate driver, the emission driver, and the data driver circuit DDC. The timing controller may control the operations of the gate driver, the emission driver, and the data driver circuit DDC.

Through the first circuit board FPCB, various signals and voltages from the timing controller on the second circuit board PCB may be supplied to the gate driver and emission driver. These include a gate timing control signal, an emission timing control signal, a gate clock signal, an emission clock signal, a gate start signal, an emission start signal, a high-potential voltage, and a low-potential voltage. For example, the gate driver may receive the gate timing control signal, the gate clock signal, the gate start signal, the high-potential voltage and the low-potential voltage, while the emission driver may receive the emission timing control signal, the emission clock signal, the emission start signal, the high-potential voltage and the low-potential voltage. In addition, power signals from the power supply unit disposed on the second circuit board PCB may be supplied to the gate driver, the emission driver, and the pixels PX through the first circuit board FPCB. The power signals may include, for example, a driving voltage, a common voltage, an initialization voltage, and a bias voltage.

As illustrated in FIG. 2, a plurality of pads PD may be disposed in the non-display area NDA of the display panel DSP. For example, the pads PD may be disposed close to an edge (e.g., the third side S3) of the display panel DSP. Here, the pads PD may be arranged along the third side S3. For example, the pads PD may be arranged along the first direction DR1. More specifically, the pads PD may be arranged in rows along the first direction DR1 and columns along the second direction DR2.

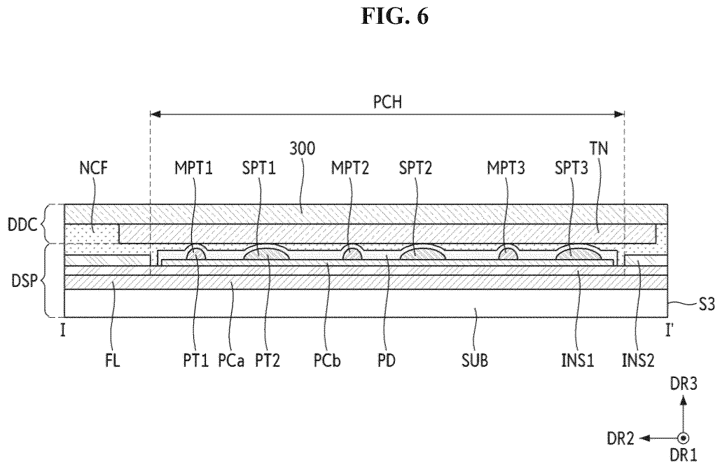

The pads PD of the display panel DSP may be connected to a plurality of terminals (or bumps; e.g., TN in FIG. 6) of the driver circuit DDC. Among the pads PD of FIG. 2, those positioned closer to the third side S3, such as input pads, may transmit signals from the first circuit board FPCB and the second circuit board PCB to the driver circuit DDC. Among the pads PD of FIG. 2, those located closer to the display area DA, such as output pads, may transmit signals from the driver circuit DDC to the pixels PX of the display area DA.

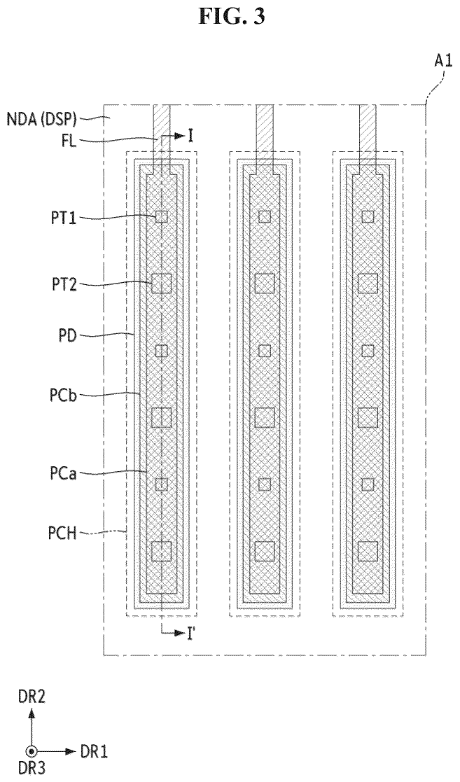

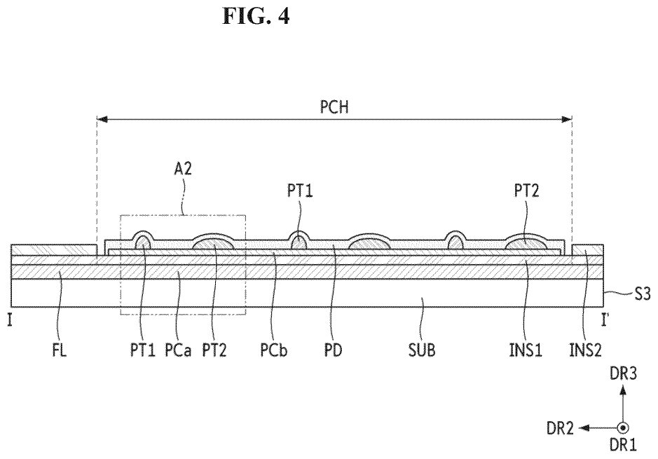

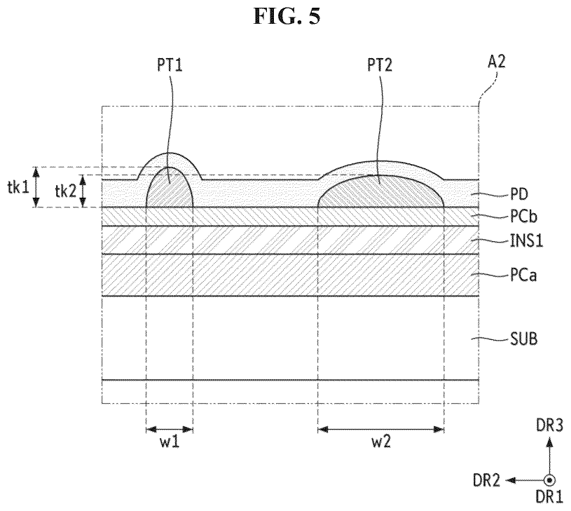

FIG. 3 is an enlarged view of area A1 of FIG. 2. FIG. 4 is a cross-sectional view taken along line I-I′ of FIG. 3. FIG. 5 is an enlarged view of area A2 of FIG. 4.

First pad connection electrodes PCa may be disposed on a substrate SUB of the display panel DSP. Each of the first pad connection electrodes PCa may include a conductive material including molybdenum (Mo), aluminum (Al), copper (Cu), titanium (Ti), etc. and may be formed as a multilayer or single layer including the above materials. A first insulating layer INS1 may be disposed on the first pad connection electrodes PCa.

Second pad connection electrodes PCb may be disposed on the first insulating layer INS1 to overlap the first pad connection electrodes PCa. The second pad connection electrodes PCb may be connected to the first pad connection electrodes PCa. To this end, an extension of each second pad connection electrode PCb, which extends toward the display area DA, may be connected to a fan-out line FL through a contact hole that penetrates the first insulating layer INS1. The fan-out lines FL may be formed integrally with the first pad connection electrodes PCa. Each of the second pad connection electrodes PCb may include aluminum (Al), platinum (Pt), palladium PD, silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may be a single layer or multilayer of the above materials.

A second insulating layer INS2 may be disposed on the second pad connection electrodes PCb. The second insulating layer INS2 may contact (or directly contact) the second pad connection electrodes PCb. The second insulating layer INS2 may have pad contact holes PCH.

First protruding patterns PT1 and second protruding patterns PT2 may be disposed on each of the second pad connection electrodes PCb. The first protruding patterns PT1 and the second protruding patterns PT2 may contact (or directly contact) each of the second pad connection electrodes PCb. The first protruding patterns PT1 may include a polymer-based material. Examples of the polymer-based material may include acrylic resin, epoxy resin, polyimide, and polyethylene. The second protruding patterns PT2 may be made of the same material as the first protruding patterns PT1.

The pads PD may be disposed on the second insulating layer INS2, the first protruding patterns PT1, the second protruding patterns PT2, and the second pad connection electrodes PCb. The pads PD may contact (or directly contact) the second insulating layer INS2, the first protruding patterns PT1, the second protruding patterns PT2, and the second pad connection electrodes PCb. The pads PD may be connected to the fan-out lines FL. For example, the pads PD may be connected to the fan-out lines FL through the second pad connection electrodes PCb and the first pad connection electrodes PCa. The fan-out lines FL may be connected to, for example, data lines. Each of the pads PD may include a conductive material including molybdenum (Mo), aluminum (Al), copper (Cu), titanium (Ti), etc. and may be formed as a multilayer or single layer including the above materials.

Since a plurality of protruding patterns PT1 and PT2 are disposed along a longitudinal direction (e.g., the second direction DR2) of each pad PD, each pad PD on the protruding patterns PT1 and PT2 may have an uneven shape as illustrated in FIG. 4. For example, each pad PD may include elevated portions protruding along a third direction DR3 and recessed portions along the opposite direction (hereinafter, referred to as the third reverse direction. Specifically, the pads PD protrude in the third direction DR3 on the protruding patterns PT1 and PT2 and are recessed in the third reverse direction between adjacent protruding patterns PT1 and PT2. The protruding portions of the pads PD in the third direction DR3 may contact (or directly contact) terminals TN of the driver circuit DDC, establishing an electrical connection between the pads PD of the display panel DSP and the terminals TN of the driver circuit DDC.

The first protruding patterns PT1 and the second protruding patterns PT2 may have different sizes. Accordingly, in some embodiments, the areas of the first protruding patterns PT1 and second protruding patterns PT2 may differ, and their thicknesses (or heights) may also vary.

For example, in a plan view as illustrated in FIG. 3, the area of the first protruding patterns PT1 may be smaller than the area of the second protruding patterns PT2. Here, the area may be a size in the first direction DR1 and the second direction DR2. According to an embodiment, the area of the first protruding patterns PT1 may be 0.17 to 0.99 times the area of the second protruding patterns PT2. According to an embodiment, [symbol] as illustrated in FIG. 5, a width w1 of the first protruding patterns PT1 may be 0.81 to 4.7 , and a width w2 of the second protruding patterns PT2 may be 4.8 [symbol] . Here, the width may be a size in the second direction DR2. In other words, the width w1 of the first protruding pattern PT1 is less than the width w2 of the second protruding pattern PT2. A length of the first protruding patterns PT1 may be equal to the width w1 of the first protruding pattern PT1, and a length of the second protruding patterns PT2 may be equal to the width w2 of the second protruding patterns PT2.

Here, the length may be a size in the first direction DR1.

When the first protruding patterns PT1 and the second protruding patterns PT2 each have a circular shape in a plan view, the width w1 and length of the first protruding patterns PT1 correspond to a diameter of the first protruding patterns PT1, and the width w2 and length of the second protruding patterns PT2 correspond to a diameter of the second protruding patterns PT2.

In a cross section as illustrated in FIGS. 4 and 5, a thickness tk1 (or height) of the first protruding patterns PT1 may be greater than a thickness tk2 (or height) of the second protruding patterns PT2. Here, the thickness tk1 or tk2 (or height) may be a size in the third direction DR3. According to an embodiment, the thickness tk1 of the first protruding patterns PT1 may be 1.1 to 1.5 times the thickness tk2 of the second protruding patterns PT2. According to an embodiment, the thickness tk1 of the first protruding patterns PT1 may be greater than 2.1 , and the thickness tk2 of the second protruding patterns PT2 may be 2.1 .

According to an embodiment, a difference (e.g., an absolute value of the difference) between the area of the first protruding patterns PT1 and the area of the second protruding patterns PT2 may be greater than 0.

According to an embodiment, a difference (e.g., an absolute value of the difference) between the thickness tk1 of the first protruding patterns PT1 and the thickness tk2 of the second protruding patterns PT2 may be greater than 0.2 .

The first protruding patterns PT1 may have a quadrilateral shape in a plan view as illustrated in FIG. 3. However, the present disclosure is not limited thereto, and the first protruding patterns PT1 may have various shapes such as a circle and a triangle in a plan view.

In a cross section as illustrated in FIGS. 4 and 5, the first protruding patterns PT1 may have a parabolic or lens shape that is convex in the third direction DR3 (e.g., toward the driver circuit DDC). However, the present disclosure is not limited thereto, and the first protruding patterns PT1 may have various shapes such as a quadrilateral, an oval, and a trapezoid in a cross section.

The second protruding patterns PT2 may have a quadrilateral shape in a plan view as illustrated in FIG. 3. However, the present disclosure is not limited thereto, and the second protruding patterns PT2 may have various shapes such as a circle and a triangle in a plan view.

In a cross section as illustrated in FIGS. 4 and 5, the second protruding patterns PT2 may have a parabolic or lens shape that is convex in the third direction DR3 (e.g., toward the driver circuit DDC). However, the present disclosure is not limited thereto, and the second protruding patterns PT2 may have various shapes such as a quadrilateral, an oval, and a trapezoid in a cross section.

The first protruding patterns PT1 and the second protruding patterns PT2 may have the same shape. For example, in a plan view as illustrated in FIG. 3, the first protruding patterns PT1 and the second protruding patterns PT2 may have the same quadrilateral shape but have different areas.

In a cross section as illustrated in FIGS. 4 and 5, when each of the first protruding patterns PT1 and the second protruding patterns PT2 have a curved shape, a radius of curvature of the first protruding patterns PT1 may be smaller than a radius of curvature of the second protruding patterns PT2. For example, upper surfaces of the first protruding patterns PT1 and upper surfaces of the second protruding patterns PT2 may each be curved. The upper surfaces of the first protruding patterns PT1 and the upper surfaces of the second protruding patterns PT2 may face a terminal TN of the driver circuit DDC.

A modulus of the first protruding patterns PT1 may be smaller than or equal to a modulus of the second protruding patterns PT2. For example, when the modulus of the second protruding patterns PT2 is 1, the modulus of the first protruding patterns PT1 may be smaller than 1. For example, an elastic modulus of the first protruding patterns PT1 may be greater than an elastic modulus of the second protruding patterns PT2.

The number of first protruding patterns PT1 and the number of second protruding patterns PT2 included in one pad PD may be equal to each other. For example, as illustrated in FIG. 3, one pad PD may be disposed on three first protruding patterns PT1 and three second protruding patterns PT2. However, the present disclosure is not limited thereto, and the number of first protruding patterns PT1 and the number of second protruding patterns PT2 may be different from each other.

The first protruding patterns PT1 and the second protruding patterns PT2 within a single pad PD may be arranged alternately on a second pad connection electrode PCb. For example, as illustrated in FIGS. 3 and 4, the first protruding patterns PT1 and the second protruding patterns PT2 may be alternately positioned along the longitudinal direction (or extending direction, second direction DR2) of the pad PD.

FIG. 6 is a cross-sectional view of the display device 100 when the display panel DSP according to an embodiment and the driver circuit DDC are bonded parallel to each other.

As illustrated in FIG. 6, the driver circuit DDC may include a substrate 300 (e.g., a wafer) and a plurality of terminals TN. The terminals TN of the driver circuit DDC may be disposed between the substrate 300 and the pads PD. Therefore, the terminals TN of the driver circuit DDC may overlap a plurality of first protruding patterns PT1 and a plurality of second protruding patterns PT2 of the pads PD. A plurality of transistors (or chips) may be disposed on the substrate 300 of the driver circuit DDC. Therefore, the terminals TN of the driver circuit DDC may be connected to the transistors of the driver circuit DDC. Each of the terminals TN may include aluminum (Al), platinum (Pt), palladium PD, silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may be a single layer or multilayer of the above materials.

A non-conductive film NCF may be disposed between the display panel DSP and the driver circuit DDC. For example, the non-conductive film NCF may be disposed between the pads PD of the display panel DSP and the terminals TN of the driver circuit DDC. The display panel DSP and the driver circuit DDC may be bonded to each other by the non-conductive film NCF. The non-conductive film NCF may be made of a material including, for example, resin.

As illustrated in FIG. 6, when the display panel DSP and the driver circuit DDC are bonded substantially parallel to each other along the second direction DR2, each pad PD may contact a terminal TN of the driver circuit DDC at both the first protruding patterns PT1 and the second protruding patterns PT2. For example, each pad PD may contact a terminal TN across all of the protruding patterns PT1 and PT2. As a specific example, three first protruding patterns PT1 may be designated as a first main protruding pattern MPT1, a second main protruding pattern MPT2 and a third main protruding pattern MPT3. Similarly, three second protruding patterns PT2 may be designated as a first sub-protruding pattern SPT1, a second sub-protruding pattern SPT2 and a third sub-protruding pattern SPT3. In this case, a pad PD may contact (or directly contact) a terminal TN of the driver circuit DDC at the first through third main protruding patterns MPT1 through MPT3 and the first through third sub-protruding patterns SPT1 through SPT3. Specifically, the pad PD may contact (or directly contact) the terminal TN of the driver circuit DDC at multiple points: between the first main protruding pattern MPT1 and the terminal TN; between the second main protruding pattern MPT2 and the terminal TN; between the third main protruding pattern MPT3 and the terminal TN; between the first sub-protruding pattern SPT1 and the terminal TN; between the second sub-protruding pattern SPT2 and the terminal TN; and between the third sub-protruding pattern SPT3 and the terminal TN.

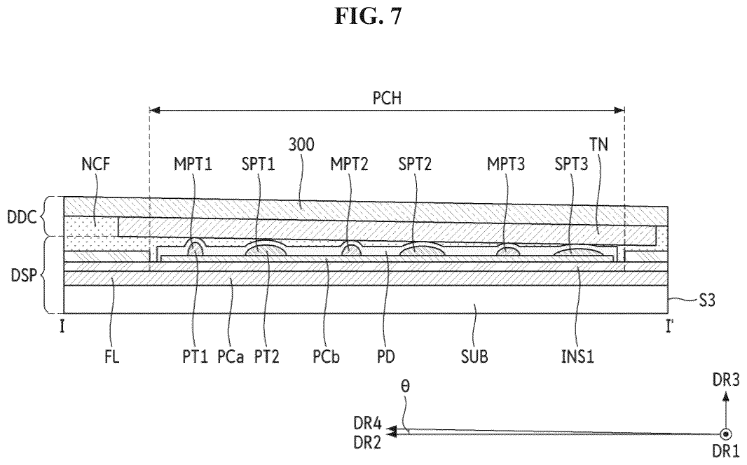

FIG. 7 is a cross-sectional view of the display device 100 when the display panel DSP according to the embodiment and the driver circuit DDC are not bonded parallel to each other.

As illustrated in FIG. 7, due to process conditions, the display panel DSP and the driver circuit DDC may be bonded in a non-parallel arrangement. For example, as illustrated in FIG. 7, an internal angle θ formed by the display panel DSP and the driver circuit DDC may be an acute angle. Specifically, in a cross section as illustrated in FIG. 7, the angle θ formed by a lower surface of a protruding pattern PT1 or PT2 beneath a pad PD of the display panel DSP and a direction (e.g., a fourth direction DR4) in which a terminal TN of the driver circuit DDC extends may be an acute angle. Here, the lower surface of the protruding pattern may refer, for example, to an interface between a first protruding pattern PT1 and a second pad connection electrode PCb or an interface between a second protruding pattern PT2 and the second pad connection electrode PCb.

When the driver circuit DDC is bonded to the display panel DSP at a tilt along a diagonal direction (e.g., the fourth direction DR4), each pad PD may contact a terminal TN of the driver circuit DDC on some of the protruding patterns PT1 and PT2. For example, a pad PD may contact (or directly contact) a terminal TN of the driver circuit DDC on the first main protruding pattern MPT1, the second main protruding pattern MPT2, the third main protruding pattern MPT3, the second sub-protruding pattern SPT2, and the third sub-protruding pattern SPT3. However, the pad PD may not contact the terminal TN of the driver circuit DDC on the first sub-protruding pattern SPT1. Specifically, the pad PD may contact (or directly contact) the terminal TN of the driver circuit DDC at the following locations: between the first main protruding pattern MPT1 and the terminal TN; between the second main protruding pattern MPT2 and the terminal TN; between the third main protruding pattern MPT3 and the terminal TN; between the second sub-protruding pattern SPT2 and the terminal TN; and between the third sub-protruding pattern SPT3 and the terminal TN. On the other hand, the pad PD may not contact the terminal TN between the first sub-protruding pattern SPT1 and the terminal TN of the driver circuit DDC.

Since the display device 100 according to this embodiment includes the protruding patterns PT1 and PT2 of different sizes, the reduction in contact area between the pads PD of the display panel DSP and the terminals TN of the driver circuit DDC can be minimized even when the two components are bonded in a non-parallel manner. For example, since the first protruding patterns PT1 have a smaller area than the second protruding patterns PT2 but have a greater thickness t1 (or height) than the second protruding patterns PT2, the first protruding patterns PT1 can be easily deformed under lower pressure compared to the second protruding patterns PT2. In addition, since the first protruding patterns PT1 have a smaller radius of curvature than the second protruding patterns PT2, the first protruding patterns PT1 have a sharper shape toward the terminals TN of the driver circuit DDC compared to the second protruding patterns PT2. Accordingly, the first protruding patterns PT1 provide increased contact force and penetration force against the terminals TN, enhancing the electrical connection. Consequently, even when the display panel DSP and the driver circuit DDC are bonded at an angle, the first protruding patterns PT1 easily deform under bonding pressure, ensuring strong contact. In addition, since the first protruding patterns PT1 press the pads PD toward the terminals TN with high contact and penetration forces, the reduction in contact area between the pads PD of the display panel DSP and the terminals TN of the driver circuit DDC is minimized, maintain reliable electrical connectivity.

In addition, in the display device 100 according to the embodiment, since the first protruding patterns PT1 and the second protruding patterns PT2 have different thicknesses (or heights), the fluidity of the non-conductive film NCF between the display panel DSP and the driver circuit DDC is improved. This improved fluidity helps optimize the distribution of the non-conductive film NCF, thereby enhancing adhesion between the display panel DSP and the driver circuit DDC.

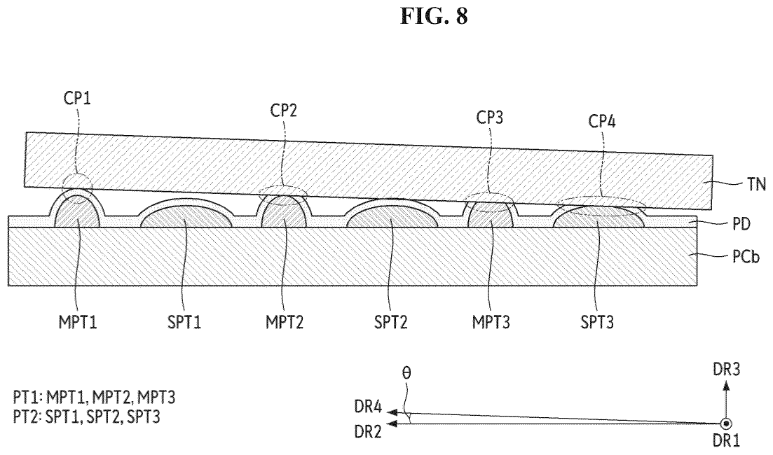

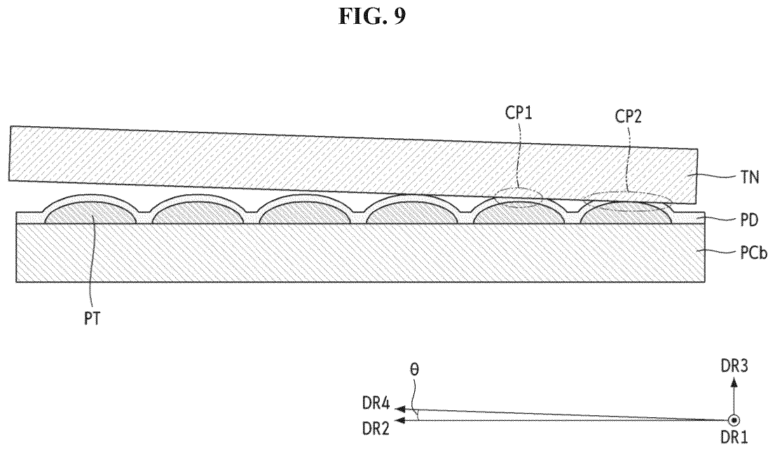

FIGS. 8 and 9 are diagrams for explaining the effect of the display device 100 according to the embodiment.

FIG. 8 illustrates a part of the display device 100 according to the embodiment, and FIG. 9 illustrates a part of a comparative display device.

As illustrated in FIG. 8, the display device 100 according to the embodiment includes the protruding patterns PT1 and PT2 with different sizes. Therefore, when the display panel DSP (e.g., a pad PD of the display panel DSP) and the driver circuit DDC (e.g., a terminal TN of the driver circuit DDC) are not bonded parallel to each other, the pad PD of the display panel DSP and the terminal TN of the driver circuit DDC may still contact each other at four contact points CP1, CP2, CP3 and CP4. For example, the pad PD of FIG. 8 may contact (or directly contact) the terminal TN of the driver circuit DDC on the first main protruding pattern MPT1, the second main protruding pattern MPT2, the third main protruding pattern MPT3, the second sub-protruding pattern SPT2, and the third sub-protruding pattern SPT3.

On the other hand, as illustrated in FIG. 9, the comparative display device includes protruding patterns PT of the same size. Therefore, when a display panel DSP (e.g., a pad PD of the display panel DSP) and a driver circuit DDC (e.g., a terminal TN of the driver circuit DDC) are not bonded parallel to each other, the pad PD of the display panel DSP and the terminal TN of the driver circuit DDC may only contact each other at two contact points CP1 and CP2. For example, as shown in FIG. 9, the pad PD contacts the terminal TN on two of the six protruding patterns PT while not making contact with the terminal TN on the remaining four protruding patterns PT.

Accordingly, in the display device 100 of this embodiment, even when the display panel DSP and the driver circuit DDC are bonded in a non-parallel manner, the reduction in contact area between the pad PD of the display panel DSP and the terminal TN of the driver circuit DDC can be minimized. Further, even under such bonding conditions, the contact resistance between the pad PD of the display panel DSP and the terminal TN of the driver circuit DDC can also be minimized, ensuring reliable electrical connectivity.

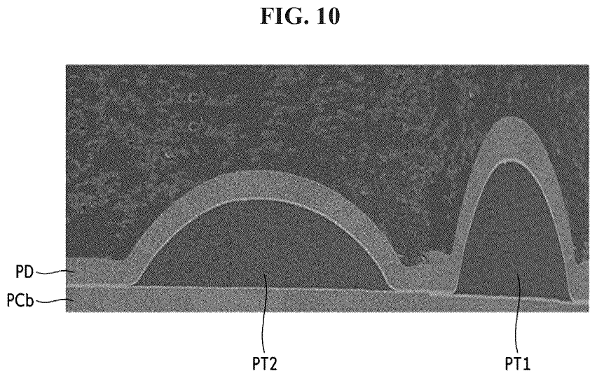

FIG. 10 is a tomogram of a part of the display device 100 according to the embodiment.

As illustrated in FIG. 10, a first protruding pattern PT1 and a second protruding pattern PT2 of different sizes may be disposed on a second pad connection electrode PCb of a pad PD, and the pad PD may be disposed on the first protruding pattern PT1 and the second protruding pattern PT2.

In a display device according to an embodiment, the contact resistance between a display panel and a driver circuit can be minimized.

For example, the display device of an embodiment may include protruding patterns with varying areas and thicknesses. As a result, even when the display panel and the driver circuit are bonded in a non-parallel manner, the reduction in contact area between a pad of the display panel and a terminal of the driver circuit can be minimized. Consequently, the contact resistance between the pad and the terminal remains low, ensuring stable electrical connectivity.

However, the effects of the present disclosure are not limited to those described herein. Additional effects will become more apparent to those skilled in the art upon review of the claims.

The display device according to the embodiments can be applied to various electronic devices. The electronic device according to an embodiment includes the display device described above and may further include modules or devices having additional functions in addition to the display device.

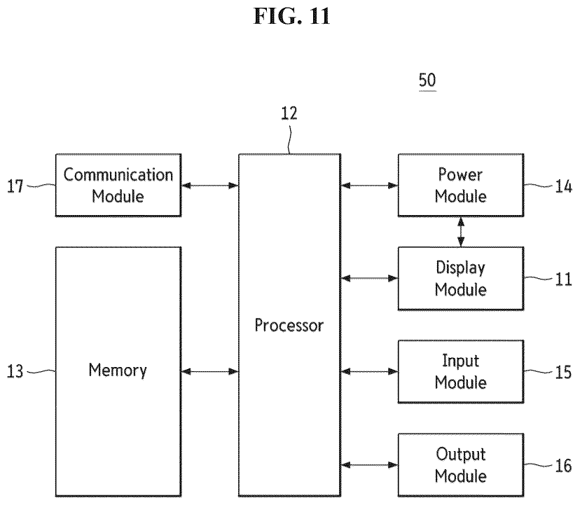

FIG. 11 is a block diagram of an electronic device according to an embodiment. Referring to FIG. 11, the electronic device 50 may include a display module 11, a processor 12, a memory 13, and a power module 14. The electronic device 5000 may further include an input module 15, an output module 16 and/or a communication module 17.

The electronic device 50 may output various information in the form of images through the display module 11. When the processor 12 executes an application stored in the memory 13, image information provided by the application may be provided to the user through the display module 11. The power module 14 may include a power supply module such as a power adapter or a battery device, and a power conversion module that converts the power supplied by the power supply module to generate power required for the operation of the electronic device 50. The input module 15 may provide input information to the processor 12 and/or the display module 11. The output module 16 may receive information other than images transmitted from the processor 12, such as sound, haptics, and light, and provide the information to a user. The communication module 17 is a module that is responsible for transmitting and receiving information between the electronic device 50 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, while the display device includes the display module 11, components such as the processor 12, memory 13, and power module 14 may be implemented as separate devices within the electronic device 50 rather than being part of the display device itself.

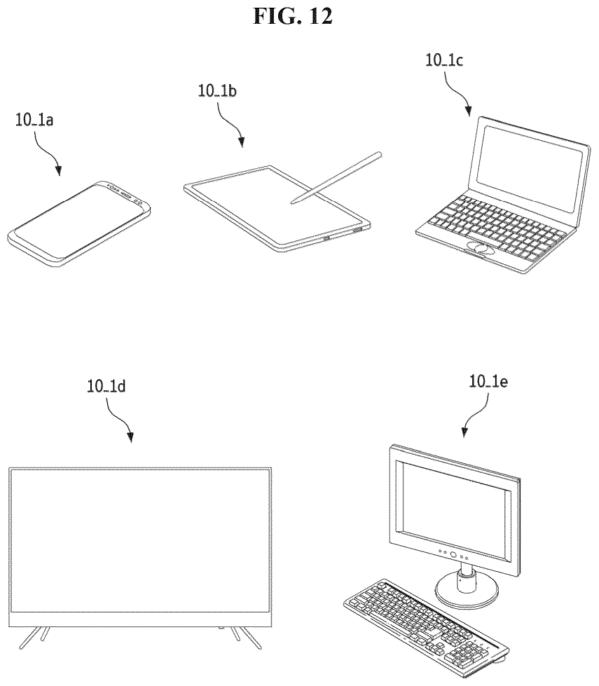

FIGS. 12, 13, and 14 are schematic diagrams of electronic devices according to various embodiments. FIGS. 12 to 14 illustrate examples of various electronic devices to which the display device according to the embodiments is applied.

FIG. 12 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of the tablet PC 10_1b, laptop 10_1c, TV 10_1d, and desk monitor 10_1e, they also include display modules and input modules similar to smartphone 10_1, and may additionally include communication modules.

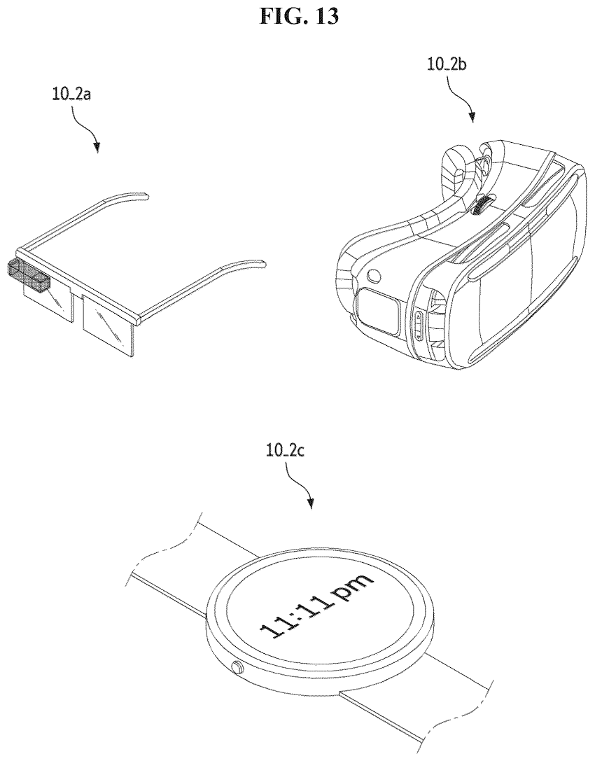

FIG. 13 shows an example of an electronic device including a display module being applied to a wearable electronic device. The wearable electronic device may be a pair of smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to a user's eyes, thereby providing a virtual reality or augmented reality screen to the user.

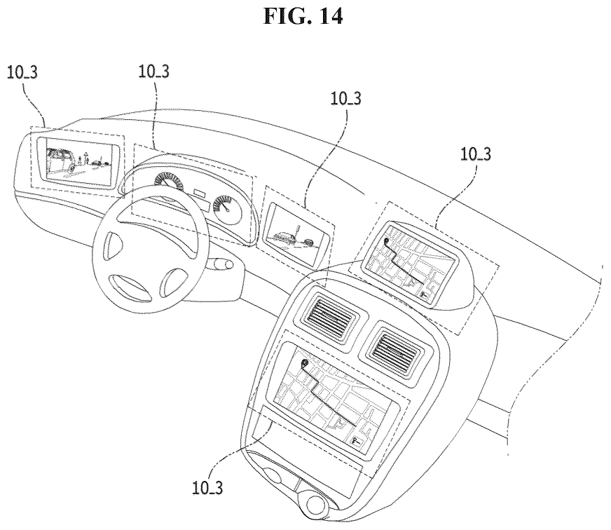

The smart watch 10_2c includes a biometric sensor as an input device, and may provide biometric information recognized by the biometric sensor to the user through the display module. FIG. 14 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

In concluding the detailed description, those skilled in the art will appreciate that many variations and modifications can be made to the disclosed embodiments without substantially departing from the principles of the present disclosure.

What is claimed is:

1. A display device comprising:
a display panel;
a driver circuit connected to a pad of the display panel; and
a first protruding pattern and a second protruding pattern disposed between a substrate of the display panel and the pad and protruding toward a terminal of the driver circuit,
wherein an area of the first protruding pattern is less than an area of the second protruding pattern, and a thickness of the first protruding pattern is greater than a thickness of the second protruding pattern.

2. The display device of claim 1, wherein the first protruding pattern and the second protruding pattern are alternately disposed along a direction in which the pad extends.

3. The display device of claim 1, wherein the first protruding patterns and the second protruding patterns are equal in number.

4. The display device of claim 1, wherein the first protruding patterns and the second protruding patterns are different in number.

5. The display device of claim 1, wherein a modulus of the first protruding pattern is less than or equal to a modulus of the second protruding pattern.

6. The display device of claim 1, wherein a surface of each of the first protruding pattern and the second protruding pattern, which faces the terminal, has a curved shape.

7. The display device of claim 6, wherein a radius of curvature of the first protruding pattern is less than a radius of curvature of the second protruding pattern.

8. The display device of claim 1, wherein the first protruding pattern and the second protruding pattern have the same shape.

9. The display device of claim 8, wherein each of the first protruding pattern and the second protruding pattern has a quadrilateral shape in a plan view.

10. The display device of claim 8, wherein each of the first protruding pattern and the second protruding pattern has a parabolic shape or a lens shape in a cross section.

11. The display device of claim 1, wherein the first protruding pattern and the second protruding pattern are made of the same material.

12. The display device of claim 1, wherein the display panel and the driver circuit are disposed parallel to each other.

13. The display device of claim 12, wherein a direction in which the pad of the display panel extends is parallel to a direction in which the terminal of the driver circuit extends.

14. The display device of claim 13, wherein the pad contacts the terminal between the first protruding pattern and the terminal and contacts the terminal between the second protruding pattern and the terminal,
wherein each of the first protruding pattern and the second protruding pattern is provided in a plural number, and the pad contacts the terminal between a plurality of first protruding pattens and the terminal and contacts the terminal between a plurality of second protruding patterns and the terminal.

15. The display device of claim 1, wherein the display panel and the driver circuit are arranged in a non-parallel configuration.

16. The display device of claim 15, wherein a direction in which the pad of the display panel extends is not parallel to a direction in which the terminal of the driver circuit extends.

17. The display device of claim 16, wherein an angle formed by the direction in which the pad of the display panel extends and the direction in which the terminal of the driver circuit extends is acute.

18. The display device of claim 16, wherein the pad contacts the terminal between the second protruding pattern and the terminal,
wherein each of the first protruding pattern and the second protruding pattern is provided in a plural number, and the pad contacts the terminal between some of a plurality of first protruding patterns and the terminal and contacts some of a plurality of second protruding patterns and the terminal.

19. An electronic device comprising:
a display device including a screen,
wherein the display device comprises:
a display panel;
a driver circuit connected to a pad of the display panel; and
a first protruding pattern and a second protruding pattern disposed between a substrate of the display panel and the pad and protruding toward a terminal of the driver circuit,
wherein an area of the first protruding pattern is less than an area of the second protruding pattern, and a thickness of the first protruding pattern is greater than a thickness of the second protruding pattern.

20. A display device comprising:
a display panel;
a driver circuit connected to a pad of the display panel; and
a plurality of protruding patterns disposed between a substrate of the display panel and the pad, the plurality of protruding patterns protruding toward a terminal of the driver circuit,
wherein the plurality of protruding patterns includes protruding patterns of different sizes and/or thicknesses.
